(19) United States
(12) Patent Application Publication
(10) Pub. No.: US 2010/0295105 A1
(43) Pub. Date: Nov. 25, 2010

(54) SEMICONDUCTOR DEVICE AND METHOD FOR MANUFACTURING THE SAME

(75) Inventors: Yasumori Fukushima, Osaka-shi (JP); Kazuhide Tomiyasu, Osaka-shi (JP); Yutaka Takafuji, Osaka-shi (JP); Kenshi Tada, Osaka-shi (JP); Michiko Takei, Osaka-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/746,323

(22) PCT Filed: Sep. 25, 2008
(86) PCT No.: PCT/JP2008/002659

§ 371 Date: Jun. 4, 2010

(30) Foreign Application Priority Data
Dec. 27, 2007 (JP) 2007-336332

(51) Int. Cl. H01L 29/78; H01L 21/762; H01L 29/73; H01L 29/861; H01L 21/331; H01L 21/336

(52) U.S. Cl. 257/288; 438/458; 257/565; 257/653; 438/309; 438/197; 257/E21.568; 257/E21.372; 257/E21.409; 257/E29.255; 257/E29.174; 257/E29.327

(57) ABSTRACT

A method for manufacturing a semiconductor device includes: an element portion formation step of forming an element portion on a base layer; a delaminating layer formation step of forming a delaminating layer in the base layer; a bonding step of bonding the base layer having the element portion to a substrate; and a separation step of separating and removing a portion of the base layer in the depth direction along the delaminating layer by heating the base layer bonded to the substrate. The method further includes, after the separation step, an ion implantation step of ion-implanting a p-type impurity element in the base layer for adjusting the impurity concentration of a p-type region of the element.

### TECHNICAL FIELD

The present disclosure relates to a semiconductor device applied to a liquid crystal display, for example, and a method for manufacturing such a semiconductor device.

### BACKGROUND ART

In recent years, demands for liquid crystal displays have been significantly increasing for use as thin displays for mobile equipment such as cellular phones and so-called liquid crystal display TVs. Such a liquid crystal display includes a liquid crystal layer sandwiched between a pair of substrates. One of the substrates includes a plurality of thin film transistors (TFTs) formed on a glass substrate.

An SOI (silicon on insulator) substrate is conventionally known, which is a silicon substrate having a monocrystalline silicon layer formed on the surface of an insulating layer. By forming elements such as transistors on an SOI substrate, it is possible to reduce the parasitic capacitance as well as increasing the insulation resistance. In other words, enhancement in the performance and integration of the elements can be attained. The insulating layer is formed of a silicon oxide (SiO₂) film, for example.

In the above SOI substrate, it is desirable to thin the monocrystalline silicon layer from the standpoint of increasing the operation speed of the elements and further reducing the parasitic capacitance. In general, a variety of methods are known to form an SOI substrate, including mechanical polishing, chemical mechanical polishing (CMP), and use of porous silicon. As an example of a method involving hydrogen implantation, Bruel proposes Smart-Cut process in which hydrogen is implanted in a semiconductor substrate, and after being bonded to a second substrate, the semiconductor substrate is split along its hydrogen-implanted layer by heat treatment, thereby to transfer a portion of the semiconductor substrate to the second substrate (see Non-Patent Documents 1 and 2).

With the above technique, an SOI substrate can be formed, which is a silicon substrate having a monocrystalline silicon layer formed on the surface of an insulating layer. By forming elements such as transistors on such a substrate structure, the parasitic capacitance can be reduced and the insulating resistance can be enhanced, whereby enhancement in the performance and integration of the elements can be achieved.

### Citation List

### Non-Patent Document

NON-PATENT DOCUMENT 1: Electronics Letters, Vol. 31, No. 14, 1995, pp. 1201

NON-PATENT DOCUMENT 2: JJAP, Vol. 36 (1997), pp. 1636

NON-PATENT DOCUMENT 3: Applied Physics Letters, 43(2), 15 Jul. 1983, “Deactivation of the boron acceptor in silicon by hydrogen”

NON-PATENT DOCUMENT 4: Journal of Applied Physics, 75(7), 1 Apr. 1994, “Hydrogen introduction and hydrogen-enhanced thermal donor formation”

### SUMMARY OF THE INVENTION

### Technical Problem

The present inventors have found the following: by separating a portion of a semiconductor substrate, on which at least part of a semiconductor element such as a MOS transistor has been formed, from the other portion thereof along a hydrogen-implanted layer formed in the semiconductor substrate, the semiconductor element can be manufactured as a thinned element on a second substrate. By using a transparent substrate as the second substrate, the resultant semiconductor device having a thinned semiconductor layer can be applied to a liquid crystal display.

However, the inventors have found from their repeated intensive researches that the threshold voltages of an NMOS transistor and a PMOS transistor formed on the second substrate as thinned elements shift in the negative voltage direction by as large as about 1 V or more. With such fluctuations in threshold voltage, the threshold values, the drain current values, and the like of the NMOS transistor and the PMOS transistor go out of balance, causing a problem that a CMOS circuit and the like constructed of the NMOS transistor and the PMOS transistor fails to operate normally.

The following are considered as causes for the shift of the threshold voltages in the negative voltage direction. First, part of a p-type impurity element such as boron introduced into the channel regions of the NMOS transistor and the PMOS transistor for threshold value control may be deactivated by bonding with hydrogen implanted for splitting of the semiconductor substrate, losing the original action as the p-type impurity element. As another cause, thermal donors may be formed from oxygen atoms existing in the silicon substrate with involvement of hydrogen, changing the channel regions to n-type regions (see Non-Patent Documents 3 and 4). As a result, the actual threshold voltages are expected to shift from their target threshold voltages in the negative voltage direction.

Considering the deactivation of the p-type impurity element by bonding with hydrogen and the change of the channel regions to n-type regions by thermal donor formation described above, the dose of the p-type impurity such as boron into channel formation regions may be increased in advance, so that the concentration of the p-type impurity electrically functioning as the acceptor can be finally adjusted properly.

To use the above measures, however, it is necessary to control the amount of deactivation of the p-type impurity element and the amount of change to n-type regions by the thermal donor formation precisely with good repeatability. According to the findings obtained from experiments and the like by the present inventors, when heat treatment at about 600° C. was performed after formation of a thinned transistor on a glass substrate, the proportion of the effectively functioning p-type impurity was about 10% to 20% of the p-type impurity element initially ion-implanted in the transistor.

The proportion of the effective p-type impurity can be enhanced by further increasing the heat treatment temperature (to 700° C. or higher). However, considering the fact that the strain point of the glass substrate (the temperature at and below which no strain occurs) is about 600 to 700° C., it is difficult to raise the heat treatment temperature.

Accordingly, in the method described above, in which the proportion of the effective p-type impurity is comparatively small and varies, it is difficult to control the threshold value of the transistor with good accuracy and repeatability. Also, since a large amount of impurity element ions are to be introduced into the channel of the transistor, the mobility may be reduced due to scattering of the impurity element.

It is an object of the present invention to form an element once formed on a base layer on another substrate as a thinned element and adjust the impurity concentration of a p-type region of the element properly with good accuracy and repeatability.

### Solution to the Problem

To attain the above object, the method for manufacturing a semiconductor device of the present invention includes: an element portion formation step of forming an element portion including at least part of an element on a base layer; a delaminating layer formation step of forming a delaminating layer by ion-implanting a substance for delamination in the base layer; a bonding step of bonding the base layer having the element portion to a substrate; and a separation step of separating and removing a portion of the base layer in the depth direction in which the element portion is not formed along the delaminating layer by heating the base layer bonded to the substrate, wherein the method further includes, after the separation step, an ion implantation step of ion-implanting a p-type impurity element in the base layer for adjusting the impurity concentration of a p-type region of the element.

Preferably, the method further includes, after the separation step, a heat treatment step of heating the base layer to remove the substance for delamination from the base layer.

The method may further include an insulating film formation step of forming an insulating film covering a surface of the base layer subjected to the delamination, wherein in the ion implantation step, the p-type impurity element may be ion-implanted in the base layer through the insulating film.

The method may further include: after the separation step, a heat treatment step of heating the base layer to remove the substance for delamination from the base layer; and an insulating film formation step of forming an insulating film covering a surface of the heat-treated base layer subjected to the delamination, wherein in the ion implantation step, the p-type impurity element may be ion-implanted in the base layer through the insulating film.

The p-type impurity element is preferably boron.

The substrate may be a glass substrate or a monocrystalline silicon semiconductor substrate.

The base layer preferably includes at least one selected from the group consisting of monocrystalline silicon semiconductors, IV group semiconductors, II-VI group compound semiconductors, III-V group compound semiconductors, IV-IV group compound semiconductors, mixed crystals thereof including their homologous elements, and oxide semiconductors thereof.

The substance for delamination is preferably hydrogen or an inert element.

The element may be at least one of a MOS transistor, a bipolar transistor, and a diode.

The element may be a MOS transistor, and the p-type region may be a channel region of the MOS transistor.

The element may be a bipolar transistor, and the p-type region may be a base region of the bipolar transistor.

The element may be a PN-junction diode, and the p-type region may be a p-type region of the PN-junction diode.

The semiconductor device of the present invention has a base layer bonded to a substrate, a portion of the base layer having been separated and removed along a delaminating layer containing hydrogen, the base layer having an element portion including at least part of an element formed thereon, wherein the base layer has a region containing a p-type impurity element in which the proportion of the electrically active p-type impurity element is in the range of 80% to 100% of the p-type impurity element contained in the base layer.

Alternatively, the semiconductor device of the present invention has a base layer bonded to a substrate, a portion of the base layer having been separated and removed along a delaminating layer containing hydrogen, the base layer having an element portion including at least part of an element formed thereon, wherein the semiconductor device includes an insulating film formed continuously on a surface of the base layer and a surface of a region of the substrate on which the base layer is not formed, the base layer and the insulating film contain a p-type impurity element, and the concentration distribution of the p-type impurity element contained in the base layer and the insulating film is continuous over the interface between the base layer and the insulating film.

The concentration of the p-type impurity element is preferably in the range of 5×10¹⁶ cm⁻³ to 1×10¹⁸ cm⁻³.

The carrier concentration of the electrically active p-type impurity element is preferably in the range of 5×10¹⁶ cm⁻³ to 1×10¹⁸ cm⁻³.

The p-type impurity element is preferably boron.

The substrate may be a glass substrate or a monocrystalline silicon semiconductor substrate.

The base layer preferably includes at least one selected from the group consisting of monocrystalline silicon semiconductors, IV group semiconductors, II-VI group compound semiconductors, III-V group compound semiconductors, IV-IV group compound semiconductors, mixed crystals thereof including their homologous elements, and oxide semiconductors thereof.

The element may be at least one of a MOS transistor, a bipolar transistor, and a diode.

The element may be a MOS transistor, and the p-type region may be a channel region of the MOS transistor.

The element may be a bipolar transistor, and the p-type region may be a base region of the bipolar transistor.

The element may be a PN-junction diode, and the p-type region may be a p-type region of the PN-junction diode.

Operation

The present inventors have found the following from experiments after their repeated intensive researches on semiconductor devices that are formed by bonding a base layer having an element portion to another substrate and then separating and removing a portion of the base layer along a delaminating layer.

That is, part of hydrogen as a substance for delamination introduced into the base layer such as a semiconductor layer forms pairs with a p-type impurity element such as boron, deactivating the impurity element. The remainder of the hydrogen introduced into the base layer can be removed from the base layer by heat treatment at a temperature of 600° C. or less performed after thinning of the base layer on another substrate. Therefore, a p-type impurity element such as boron newly ion-implanted in the base layer after the heat treatment can electrically function as the p-type impurity entirely without being affected by the hydrogen-involved change to n-type conductivity.

Accordingly, after thinning of a base layer having an element portion on another substrate, hydrogen contained in the base layer is removed by heat treatment at a temperature of 600° C. or less. Thereafter, a p-type impurity element such as boron for control of the threshold of a transistor is newly ion-implanted. In this way, the threshold voltage of the transistor can be controlled with good accuracy and repeatability without the p-type impurity element being affected by fluctuations in activation factor that may otherwise occur by the hydrogen-involved change to n-type conductivity. Moreover, since it is unnecessary to introduce a large amount of impurity element ions into the channel region of the transistor, the problem of reduction in mobility caused by scattering of the impurity element does not occur.

The method for manufacturing a semiconductor device of the present invention is based on the findings described above. In manufacturing the semiconductor device, an element portion formation step is first executed, in which an element portion including at least part of an element is formed on a base layer.

As the element included in the element portion, at least one of MOS transistors, bipolar transistors, and diodes, for example, may be used. The base layer can include at least one selected from the group consisting of monocrystalline silicon semiconductors, IV group semiconductors, II-VI group compound semiconductors, III-V group compound semiconductors, IV-IV group compound semiconductors, mixed crystals thereof including their homologous elements, and oxide semiconductors thereof.

Subsequently, a delaminating layer formation step is executed, in which a substance for delamination is ion-implanted in the base layer, to form a delaminating layer. As the substance for delamination, hydrogen or an inert element, for example, may be used.

A bonding step is then executed, in which the base layer having the element portion formed thereon is bonded to a substrate. As the substrate, a glass substrate or a monocrystalline silicon semiconductor substrate may be used. For example, when a glass substrate, which is transparent, is used, the resultant semiconductor device can be applied to a display such as a liquid crystal display.

A separation step is then executed, in which the base layer bonded to the substrate is heated, thereby separating and removing a portion of the base layer in the depth direction in which the element portion is not formed along the delaminating layer. The base layer is thus thinned. With the thinned base layer, the operation speed of the element can be enhanced, and the parasitic capacitance can be reduced. At this time, since the base layer is heated, the substance for delamination contained in the base layer can be removed from the base layer simultaneously with the separation/removal of the delaminating layer.

Thereafter, an ion implantation step is executed, in which a p-type impurity element is ion-implanted in the base layer for adjustment of the impurity concentration of a p-type region of the element. As the p-type impurity element, boron may be used. In this ion implantation, since the substance for delamination has been removed from the base layer in the separation step, the p-type impurity element is prevented from deactivation and hence can maintain the function as the p-type impurity element. As a result, the impurity concentration of a p-type region of the element can be adjusted properly with good accuracy and repeatability. Also, since the amount of p-type impurity element ions implanted in the base layer can be reduced, reduction in mobility due to impurity scattering can be suppressed.

The thus-manufactured semiconductor device can have a region in which the proportion of the electrically active p-type impurity element is in the range of 80% to 100% of the p-type impurity element contained in the base layer.

A heat treatment step may be executed independently after the separation step, to heat the base layer for removal of the substance for delamination from the base layer. With this step, the substance for delamination can be removed from the base layer without fail.

An insulating film formation step may be executed after the separation step, to form an insulating film covering the surface of the base layer subjected to the delamination, followed by the ion implantation step to ion-implant the p-type impurity element in the base layer through the insulating film. In this case, in the thus-manufactured semiconductor device, the concentration distribution of the p-type impurity element contained in the base layer and the insulating film is continuous over the interface therebetween.

The heat treatment step may be executed after the separation step, and thereafter, the p-type impurity element may be ion-implanted in the base layer through the insulating film formed in the insulating film formation step.

### ADVANTAGES OF THE INVENTION

According to the present invention, a p-type impurity element for adjustment of the impurity concentration of a p-type region of an element is ion-implanted in a base layer after the base layer is heated. Therefore, since a substance for delamination contained in the base layer can be removed by heating, the p-type impurity element can be prevented from deactivation, maintaining its function as the p-type impurity element. That is, the impurity concentration of a p-type region of the element can be adjusted properly with good accuracy and repeatability. Moreover, since the dose of the p-type impurity element into the base layer can be reduced while the function of the p-type impurity element is maintained, reduction in mobility due to impurity scattering can be suppressed.

### BRIEF DESCRIPTION OF THE DRAWINGS

FIG. 1 is a schematic cross-sectional view showing a structure of a main portion of a semiconductor device.

FIG. 2 is a cross-sectional view showing a thermal oxide film formed on a silicon substrate.

FIG. 3 is a cross-sectional view showing a step of implanting phosphorous ions.

FIG. 4 is a cross-sectional view showing a state where a thermal oxide film and an n-well region are formed.

FIG. 5 is a cross-sectional view showing a state where the thermal oxide film and a silicon nitride film are patterned.

FIG. 6 is a cross-sectional view showing a state where a LOCOS oxide film is formed.

FIG. 7 is a cross-sectional view showing a state where an oxide film is formed.

FIG. 8 is a cross-sectional view showing a step of implanting boron ions in the n-well region.

FIG. 9 is a cross-sectional view showing a step of implanting boron ions.

FIG. 10 is a cross-sectional view showing a state where a gate oxide film is formed.

FIG. 11 is a cross-sectional view showing a state where gate electrodes are formed.

FIG. 12 is a cross-sectional view showing a step of forming lightly doped impurity regions.

FIG. 13 is a cross-sectional view showing a step of forming lightly doped impurity regions in the n-well region.

FIG. 14 is a cross-sectional view showing a state where sidewalls are formed.

FIG. 15 is a cross-sectional view showing a step of forming heavily doped impurity regions.

FIG. 16 is a cross-sectional view showing a step of forming heavily doped impurity regions in the n-well region.

FIG. 17 is a cross-sectional view showing a state where a planarizing film is formed.

FIG. 18 is a cross-sectional view showing a state where a delaminating layer is formed.

FIG. 19 is a cross-sectional view showing a state where source and drain electrodes are formed.

FIG. 20 is a cross-sectional view showing an element portion bonded to a glass substrate.

FIG. 21 is an enlarged cross-sectional view showing a state where a portion of the silicon substrate is separated.

FIG. 22 is a cross-sectional view showing a state where ion implantation is performed through an oxide film.

FIG. 23 is a cross-sectional view showing the element portion connected to electric elements on the glass substrate.

FIG. 24 is a plan view showing a main portion of the semiconductor device.

### DESCRIPTION OF REFERENCE CHARACTERS

S Semiconductor Device

D Element Portion

1 Silicon Substrate (Base Layer)

4 N-Type Impurity Element

10 LOCOS Oxide Film

13, 15 Channel Region

16 Gate Oxide Film

17 Gate Electrode

19 N-Type Impurity Element

20 N-Type Lightly Doped Impurity Region

22 P-type Impurity Element

23 P-Type Lightly Doped Impurity Region

26 N-Type Impurity Element

27 N-Type Heavily Doped Impurity Region

29 P-Type Impurity Element

30 P-Type Heavily Doped Impurity Region

32 Substance for Delamination

33 Delaminating Layer

38 Glass Substrate (Substrate)

39 Oxide Film

40 Interlayer Insulating Film

43 Impurity Element

45 Impurity Element

50 P-Type Impurity Element, Boron

51 First Active Region

52 Second Active Region

56 PMOS Transistor

57 NMOS Transistor

### DESCRIPTION OF EMBODIMENTS

Embodiments of the present invention will be described hereinafter with reference to the accompanying drawings. Note that the present invention is not limited to the embodiments to follow.

### Embodiment 1

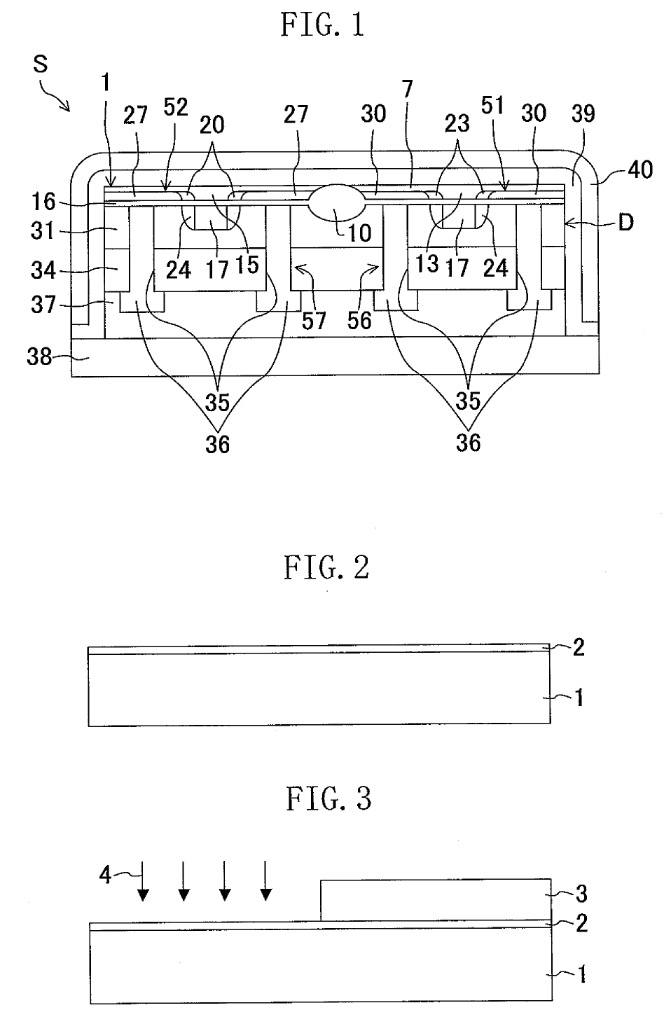

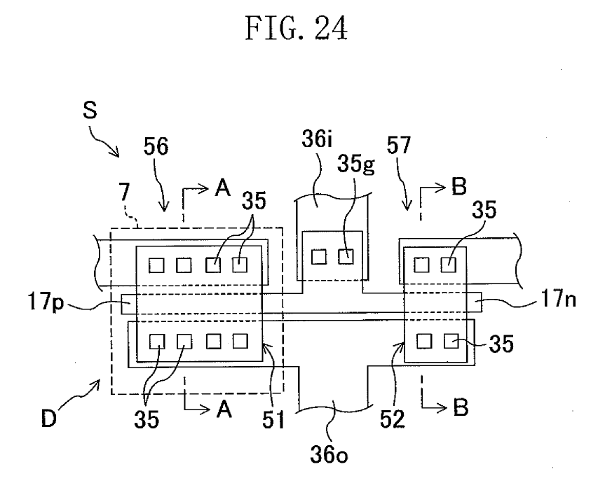

FIGS. 1-22 and 24 show Embodiment 1 of the present invention. FIG. 1 is a schematic cross-sectional view of a structure of a main portion of a semiconductor device S. FIGS. 2-22 are cross-sectional views showing process steps for manufacturing the semiconductor device S. FIG. 24 is a plan view showing a main portion of the semiconductor device S.

The semiconductor device S is formed directly on a glass substrate 38 constituting a display panel of a liquid crystal display, for example, although such a liquid crystal display is not shown in FIG. 1, and is applied as a variety of functional circuits such as a driver circuit for driving and controlling a plurality of pixels in the display panel, a power supply circuit, a clock generation circuit, an input/output circuit, and a memory circuit.

Although not shown in FIG. 1, the liquid crystal display includes a TFT substrate having a plurality of thin film transistors (TFTs) formed therein, a counter substrate opposed to the TFT substrate, and a liquid crystal layer interposed between the TFT substrate and the counter substrate. In the counter substrate, a common electrode made of ITO, for example, color filters, and the like are formed on a glass substrate. In the TFT substrate, a plurality of TFTs, pixel electrodes, and the like are formed on the glass substrate 38.

As shown in FIG. 1, the semiconductor substrate S includes the glass substrate 38 and an element portion D formed on a base layer 1 with high density and precision, which is placed on the glass substrate 38. The element portion D includes transistors 56 and 57 as elements, which are covered with a planarizing film 37. The element portion D is attached to the glass substrate 38 via the planarizing film 37 by self-bonding. In other words, the base layer 1 is bonded to the glass substrate 38 together with the element portion D.

Although a transparent substrate such as the glass substrate is preferred as the substrate 38 when the semiconductor device S is applied to liquid crystal displays that perform transmission display, other substrates such as a monocrystalline silicon semiconductor substrate may be used as the substrate 38 when the semiconductor substrate S is applied to other types of displays and the like.

As shown in FIGS. 1 and 24, the element portion D has the NMOS transistor 57 and the PMOS transistor 56 as semiconductor elements. A LOCOS oxide film 10 as a film for element isolation is formed, as shown in FIG. 1, as an element isolation region that electrically isolates the transistors 56 and 57 from each other.

Note that the schematic cross section of the PMOS transistor 56 shown on the right in FIG. 1 corresponds to section A-A in FIG. 24, and the schematic cross section of the NMOS transistor 57 shown on the left in FIG. 1 corresponds to section B-B in FIG. 24.

It should also be noted that although one NMOS transistor 57 and one PMOS transistor 56 are shown in FIGS. 1 and 24, elements to be formed are not limited to these kinds, but the present invention is applicable to any kinds of semiconductor elements. The number of elements can be any from one to several millions. The element portion D may be formed to include at least part of each element.

The base layer 1 has a first active region 51 formed in an n-well region on the right in FIG. 1 and a second active region 52 formed in a left-side region in FIG. 1. The first active region 51 constitutes the PMOS transistor 56, while the second active region 52 constitutes the NMOS transistor 57.

The first and second active regions 51 and 52 respectively have a lightly doped drain (LDD) structure including lightly doped impurity regions 23 and 20 formed on both sides of channel regions 13 and 15 and heavily doped impurity regions 30 and 27 formed on the outer sides of the lightly doped impurity regions 23 and 20.

In other words, in the first active region 51, formed are the channel region 13, the p-type lightly doped impurity regions 23 on both sides of the channel region 13, and the p-type heavily doped impurity regions 30 on the outer sides of the p-type lightly doped impurity regions 23. Likewise, in the second active region 52, formed are the channel region 15, the n-type lightly doped impurity regions 20 on both sides of the channel region 15, and the n-type heavily doped impurity regions 27 on the outer sides of the n-type lightly doped impurity regions 27.

The base layer 1 is a semiconductor layer made of a monocrystalline semiconductor, for example. The base layer 1 can also be configured to include, other than the monocrystalline silicon semiconductor, at least one selected from the group consisting of IV group semiconductors, II-VI group compound semiconductors, III-V group compound semiconductors, IV-IV group compound semiconductors, mixed crystals thereof including their homologous elements, and oxide semiconductors thereof.

A portion of the base layer 1 has been separated and removed along a delaminating layer formed by ion implantation of a substance for delamination such as hydrogen, as will be described later. With this separation/removal of a portion of the base layer 1 by heating, the base layer 1 has been thinned.

As shown in FIG. 1, the planarizing film 37 as an insulating film is formed on the surface of the glass substrate 38. An interlayer insulating film 34 and another planarizing film 31 are formed on the planarizing film 37. A gate oxide film 16 and the LOCOS oxide film 10 are formed on the planarizing film 31. On the gate oxide film 16, formed is the base layer 1 in which the first and second active regions 51 and 52 are formed. The surfaces of the base layer 1 and the LOCOS oxide film 10 are covered with an oxide film 39 as an insulating layer. The oxide film 39 is formed continuously over the surface of the base layer 1 serving as the surface of the element portion D and the surface of regions of the glass substrate 38 on which the base layer 1 is not formed. The oxide film 39 is covered with an interlayer insulating film 40.

Gate electrodes 17 and sidewalls 24 made of polysilicon, for example, are formed between the planarizing film 31 and the gate oxide film 16. The gate electrodes 17 respectively face the channel regions 13 and 15 via the gate oxide film 16, and the sidewalls 24 respectively face the lightly doped impurity regions 20 and 23 via the gate oxide film 16.

Contact holes 35 are formed through the planarizing film 31 and the interlayer insulating film 34 at positions vertically overlapping the heavily doped impurity regions 27 and 30, respectively. Source and drain electrodes 36 as metal electrodes are formed in the contact holes 35.

Thus, the semiconductor device S of Embodiment 1 has a CMOS structure. That is, as shown in FIG. 24, a metal interconnect 36i to which an input voltage is applied is electrically connected to a gate electrode 17n of the NMOS transistor 57 and a gate electrode 17p of the PMOS transistor 56 via contact holes 35g. The drain regions of the NMOS transistor 57 and the PMOS transistor 56 are electrically connected to a metal interconnect 36o from which an output voltage is retrieved.

The base layer 1 has a region in the channel region 15 of the NMOS transistor 57 or the channel region 13 of the PMOS transistor 56 that contains boron as a p-type impurity element in which the proportion of electrically active boron is in the range of 80% to 100% of the boron contained in the base layer 1. In particular, the concentration of boron in the base layer 1 is in the range of 5×10¹⁶ cm⁻³ to 1×10¹⁸ cm⁻³. Alternatively, the carrier concentration of any electrically active p-type impurity element (such as boron, for example) may be set in the range of 5×10¹⁶ cm⁻³ to 1×10¹⁸ cm⁻³.

Boron is also contained in the oxide film 39, not only in the base layer 1, and the concentration distribution of boron contained in the base layer 1 and the oxide film 39 is continuous over the interface between the base layer 1 and the oxide film 39.

Manufacturing Method

Next, a method for manufacturing the semiconductor device S will be described.

First, in an element portion formation step, the element portion D including at least part of the NMOS transistor 57 and the PMOS transistor 56 as elements is formed on the base layer 1 that is a monocrystalline silicon semiconductor layer, for example. More specifically, as shown in FIG. 2, a thermal oxide film 2 having a thickness of about 30 nm is formed on a silicon substrate 1 (corresponding to the base layer 1) as a wafer. The thermal oxide film 2 is provided for preventing pollution of the surface of the silicon substrate 1 in a later ion implantation step, but is not necessarily essential.

The silicon substrate 1 made of a monocrystalline silicon substrate is herein taken as an example of the base layer 1. The present invention is not limited to this, but the base layer 1 may be made of a material including other semiconductors. In other words, the base layer 1 can be configured to include at least one selected from the group consisting of monocrystalline silicon semiconductors, IV group semiconductors, II-VI group compound semiconductors, III-V group compound semiconductors, IV-IV group compound semiconductors, mixed crystals thereof including their homologous elements, and oxide semiconductors thereof.

As shown in FIG. 3, an n-type impurity element 4 (e.g., phosphorus) is then ion-implanted in a region that is to be the first active region 51 while a resist mask 3 is formed over a region that is to be the second active region 52. In this phosphorus ion implantation, the implantation energy is set at about 50 to 150 KeV, and the dose is set at about 1×10¹² to 1×10¹³ cm⁻².

In the above ion implantation, if, in a later step after removal of hydrogen contained in a silicon thin film of the base layer 1 bonded to the glass substrate 38, a p-type impurity such as boron is to be implanted in the entire silicon thin film including the n-well region 7, the dose of the n-type impurity element should be set to an increased amount by an equivalent to be cancelled by the p-type impurity element.

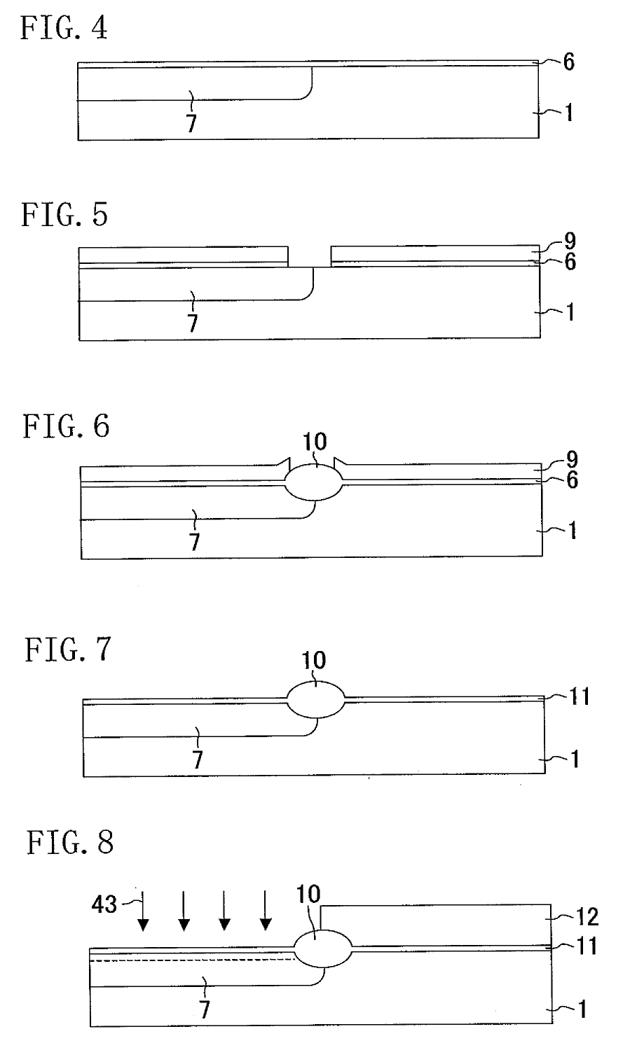

As shown in FIG. 4, after removal of the thermal oxide film 2, the substrate is subjected to heat treatment at about 900 to 1000° C. in an oxidation atmosphere, to form a thermal oxide film 6 having a thickness of about 30 nm and also allow the impurity element implanted in the n-well region 7 to be scattered forming the n-well region 7.

As shown in FIG. 5, a silicon nitride film 9 having a thickness of about 200 nm is formed on the surface of the thermal oxide film 6 by CVD and the like, and then the silicon nitride film 9 and the thermal oxide film 6 are patterned. In regions where the silicon nitride film 9 and the thermal oxide film 6 are left unremoved, the NMOS transistor 57 and the PMOS transistor 56 are to be formed in a later stage.

As shown in FIG. 6, the substrate is subjected to heat treatment at about 900 to 1000° C. in an oxygen atmosphere for LOCOS oxidation, thereby to form the LOCOS oxide film 10 having a thickness of about 200 to 500 nm, e.g., 350 nm The LOCOS oxide film 10 is formed in a region exposed through the silicon nitride film 9 and the thermal oxide film 6. In place of the LOCOS oxidation as a method for element isolation, any of other methods such as shallow trench isolation (STI) may be used for element isolation.

As shown in FIG. 7, after removal of the silicon nitride film 9 and the thermal oxide film 6, heat treatment is performed at about 1000° C. in an oxygen atmosphere, thereby to form a thermal oxide film 11 having a thickness of about 20 nm on the surface of the silicon substrate 1.

As shown in FIG. 8, a resist 12 is formed to open the region for forming the PMOS transistor 56. Subsequently, an impurity element 43 for setting the threshold voltage of the PMOS transistor 56 is introduced into the n-well region 7 by ion implantation.

At this time, if the impurity element 43 to be implanted is an n-type impurity element such as phosphorus, the ion implantation is performed. However, if the impurity element 43 is a p-type impurity element such as boron, the ion implantation is not performed at this stage, and thus the step shown in FIG. 8 is omitted. Which is to be implanted, an n-type impurity element or a p-type impurity element, should be selected appropriately depending on the material and conductivity type of the gate electrode.

For example, when n⁺polysilicon is used for the gate electrode of the PMOS transistor, boron is generally implanted for setting the threshold voltage considering the work function of the gate electrode. In this case, therefore, this step is omitted. Conversely, when p⁺ polysilicon is used for the gate electrode, phosphorus is ion-implanted at a dose of about 1×10¹² to 1×10¹³ cm⁻² with energy of about 10 to 50 KeV. The dose should be adjusted depending on the threshold voltage as the control target value.

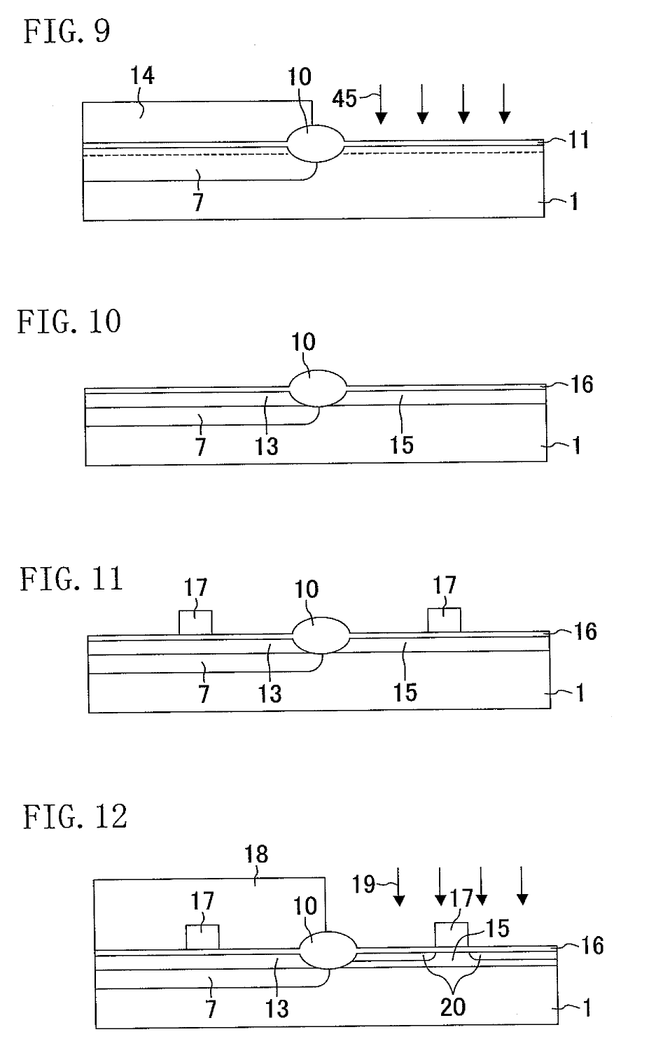

As shown in FIG. 9, a resist 14 is formed to open the region for forming the NMOS transistor 57. Subsequently, an impurity element 45 for setting the threshold voltage of the NMOS transistor 57 is introduced into the silicon substrate 1 by ion implantation.

At this time, like the case of the PMOS transistor, if the impurity element 45 to be implanted is an n-type impurity element such as phosphorus, the ion implantation is performed. However, if the impurity element 45 is a p-type impurity element such as boron, the ion implantation is not performed at this stage, and thus the step shown in FIG. 9 is omitted.

For example, when n⁺ polysilicon is used for the gate electrode of the NMOS transistor, boron is generally implanted for setting the threshold voltage considering the work function of the gate electrode. In this case, therefore, this step is omitted. Conversely, when p⁺ polysilicon is used for the gate electrode, phosphorus is implanted at a dose of about 1×10¹² to 1×10¹³ cm⁻² with energy of about 10 to 50 KeV. The dose should be adjusted depending on the threshold voltage as the control target value.

As shown in FIG. 10, after removal of the resist 14 and the thermal oxide film 11, heat treatment is performed at about 1000° C. in an oxygen atmosphere, thereby to form a gate oxide film 16 having a thickness of about 10 to 20 nm on the surface of the silicon substrate 1 including the n-well region 7.

As shown in FIG. 11, the gate electrodes 17 of the NMOS transistor 57 and the PMOS transistor 56 are then formed on the gate oxide film 16. More specifically, polysilicon is deposited on the gate oxide film 16 to a thickness of about 300 nm by CVD and the like, and then an n-type impurity element such as phosphorus is introduced into the inside of the polysilicon layer by diffusion and the like, to form an n⁺ polysilicon layer. The n⁺ polysilicon layer is then patterned by photolithography to form the gate electrodes 17.

As shown in FIG. 12, a resist 18 is then formed to open the region for forming the NMOS transistor 57 (region on the right in FIG. 12). An n-type impurity element 19 is then ion-implanted using the gate electrode 17 as a mask, thereby to form the n-type lightly doped impurity regions 20 in the silicon substrate 1. Phosphorus, for example, is used as the n-type impurity element 19. In the case of phosphorus, ion implantation is performed at a dose of about 1×10¹² to 1×10¹³ cm⁻² with energy of about 10 to 50 KeV.

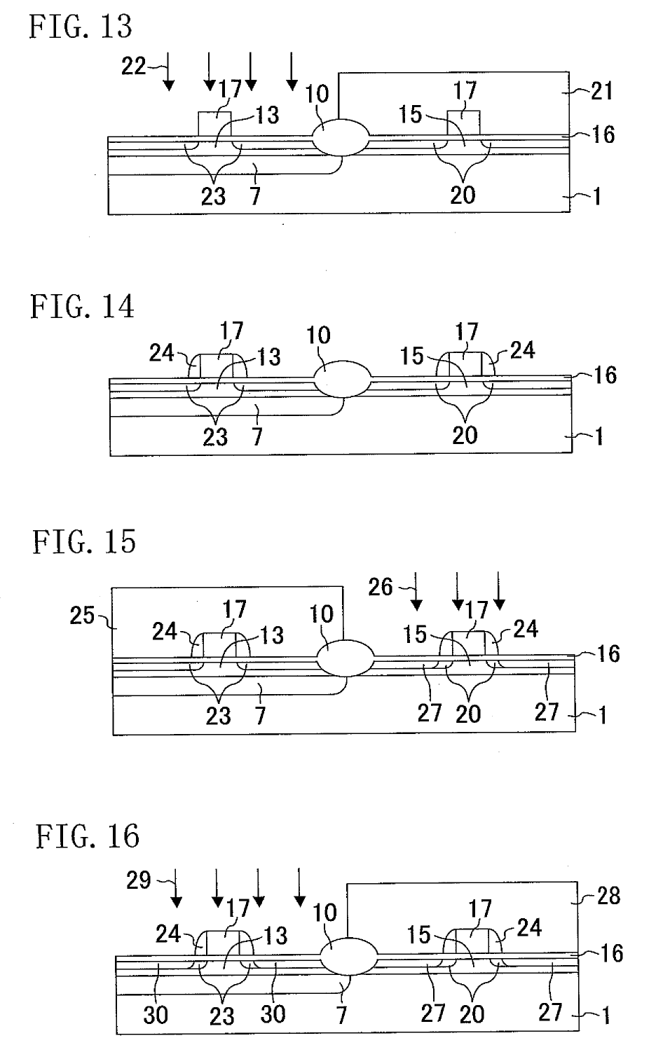

As shown in FIG. 13, a resist 21 is then formed to open the region for forming the PMOS transistor 56 (region on the left in FIG. 13). A p-type impurity element 22 is then ion-implanted using the gate electrode 17 as a mask, thereby to form the p-type lightly doped impurity regions 23.

As already discussed, part of a p-type impurity element such as boron is to be deactivated by bonding with hydrogen, losing the original action as the p-type impurity element. Also, thermal donors are formed from oxygen atoms existing in the silicon substrate 1 with involvement of hydrogen, changing the p-type impurity element to n-type one. Accordingly, the dose of the p-type impurity is set considering the proportion of the effectively functioning p-type impurity element. Boron, for example, may be used as the p-type impurity, and the ion implantation conditions in the case of boron (BF²⁺), for example, are a dose of about 5×10¹² to 5×10¹⁴ cm⁻² and energy of about 10 to 50 KeV.

Since boron is comparatively large in thermal diffusion coefficient, the p-type lightly doped impurity regions of the PMOS transistor 56 may be formed only with thermal diffusion of boron implanted for formation of the p-type heavily doped impurity regions of the PMOS transistor 56 in a later step. Accordingly, the ion implantation for formation of the p-type lightly doped impurity regions is not necessarily required.

Since the step of forming the p-type lightly doped impurity regions 23 uses the gate electrode 17 as a mask, it is necessary to perform this step at this point after the formation of the gate electrode 17. Note also that the p-type impurity element 22 introduced in this step has no direct influence on the threshold voltage of the PMOS transistor, and thus will not directly affect the accuracy and repeatability of the threshold voltage.

Thereafter, an SiO₂ film is formed by CVD and the like to cover the gate oxide film 16, the LOCOS oxide film 10, and the like. The SiO₂ film is then subjected to anisotropy etching, to form the sidewalls 24 made of SiO₂ on both outer walls of the gate electrodes 17 as shown in FIG. 14.

As shown in FIG. 15, a resist 25 is then formed to open the region for forming the NMOS transistor 57. Using the gate electrode 17 and the sidewalls 24 as a mask, an n-type impurity element 26 such as phosphorus is ion-implanted in the silicon substrate 1, thereby to form the n-type heavily doped impurity regions 27 on the outer sides of the n-type lightly doped impurity regions 20.

Subsequently, as shown in FIG. 16, a resist 28 is formed to open the region for forming the PMOS transistor 56. Using the gate electrode 17 and the sidewalls 24 as a mask, a p-type impurity element 29 such as boron is ion-implanted in the silicon substrate 1, thereby to form the p-type heavily doped impurity regions 30 on the outer sides of the p-type lightly doped impurity regions 23. Heat treatment is then performed for the region in which the impurity element has been ion-implanted, to activate the impurity element. The heat treatment is performed at 900° C. for ten minutes, for example.

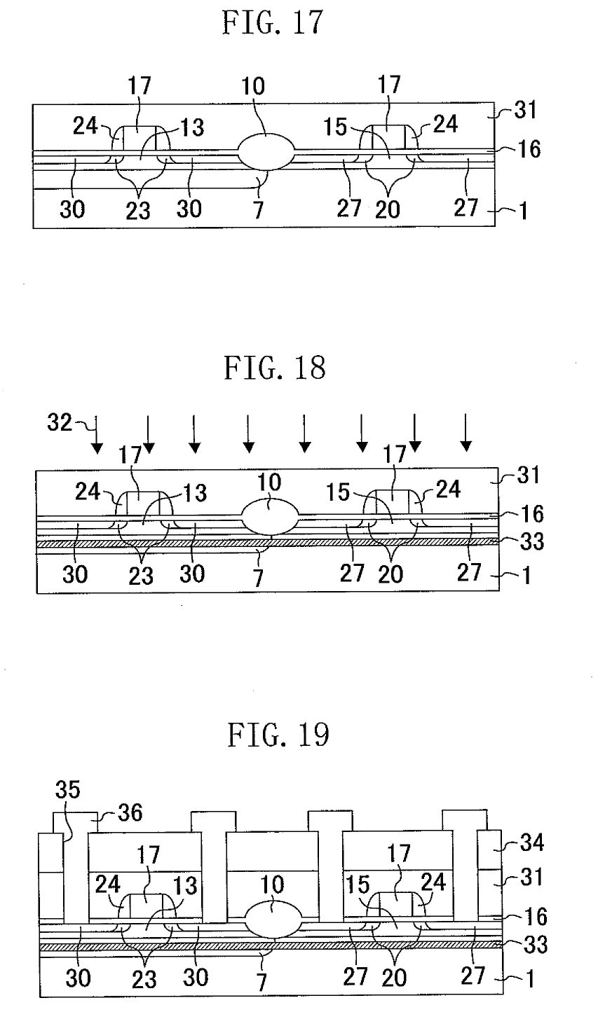

As shown in FIG. 17, an insulating film such as an SiO₂ film is formed to cover the gate electrodes 17, the sidewalls 24, and the like, and then flattened by CMP and the like to form the planarizing film 31 having a thickness of about 600 nm.

A delamination layer formation step is then performed, in which, as shown in FIG. 18, a substance 32 for delamination is ion-implanted in the silicon substrate 1 through the planarizing film 31, to form a delaminating layer 33. Hydrogen is used as the substance 32 for delamination. In place of hydrogen, or in addition to hydrogen, an inert element such as He and Ne may be used. The ion implantation conditions are a dose of about 2×10¹⁶ to 1×10¹⁷ cm⁻² and energy of about 100 to 200 KeV when the substance 32 for delamination is hydrogen.

Thereafter, as shown in FIG. 19, the interlayer insulating film 34 is formed on the surface of the planarizing film 31. The contact holes 35 are then formed through the planarizing film 31 and the interlayer insulating film 34, to expose the heavily doped impurity regions 27 and 30 at the bottoms of the contact holes 35. The contact holes 35 are then filled with a metal material, to form the source and drain electrodes 36 as metal electrodes as shown in FIG. 19.

The contact holes 35 are also formed for the gate electrodes 17 at positions not shown in the figures, and filled with a metal material to form metal electrodes for applying a voltage to the gate electrodes 17. The planarizing film 31 formed before the ion implantation of the substance 32 for delamination may be made comparatively thick, so that the contact holes 35 and the source and drain electrodes 36 can be formed without formation of the interlayer insulating film 34.

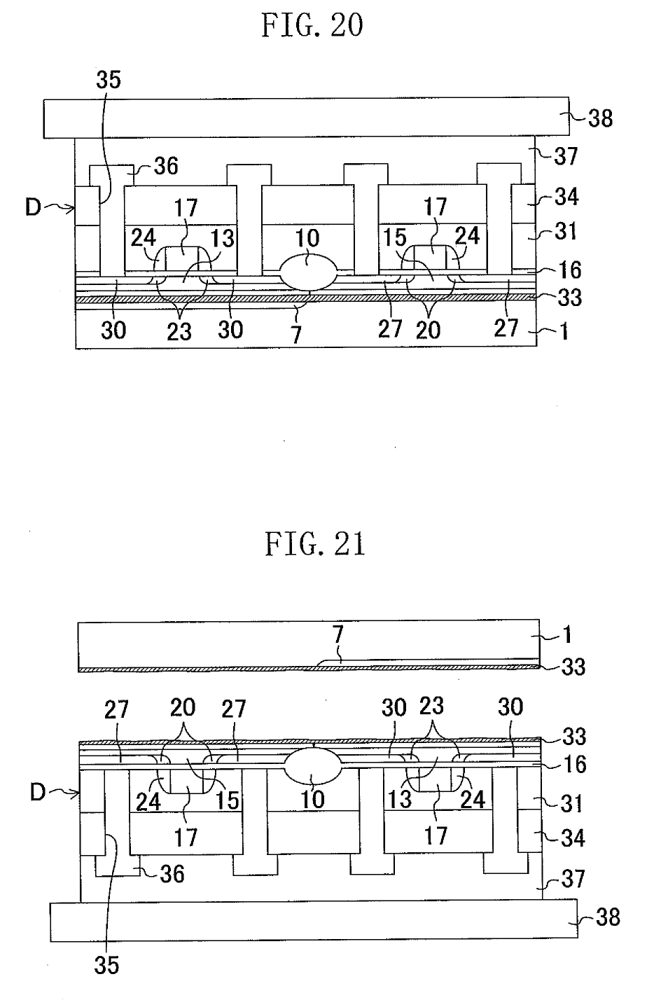

As shown in FIG. 20, a planarizing film 37 is then formed to cover the NMOS transistor 57 and the PMOS transistor 56. That is, an insulating film is first deposited on the interlayer insulating film 34 by CVD and the like, and then ground by CMP and the like to flatten the surface.

The element portion formation step is thus executed to form the element portion D including at least part of the NMOS transistor 57 and the PMOS transistor 56 on the base layer 1 as the silicon substrate 1.

Thereafter, the bonding step is executed, in which the silicon substrate 1 (base layer 1) with the element portion D formed thereon is bonded to the substrate 38. A glass substrate, for example, is used as the substrate 38. More specifically, the surface of the planarizing film 37 and the surface of the glass substrate 38 are subjected to SC1 cleaning with an SC1 solution, which is made of ammonia, hydrogen peroxide, and water, for rendering the surfaces of the objects hydrophilic. Thereafter, as shown in FIG. 20, the element portion D and the glass substrate 38 are positioned with each other and then bonded to each other at the surface of the planarizing film 37 by autohesion under the van der Waals forces.

The separation step is then performed, in which, as shown in FIG. 21, the silicon substrate 1 (base layer 1) bonded to the glass substrate 38 is heated to about 400 to 600° C., thereby to separate and remove a portion of the silicon substrate 1 (base layer 1) in its depth direction (i.e., a portion thereof opposite to the gate electrodes 17 with respect to the delaminating layer 33, where the element portion D is not formed) along the delaminating layer 33. As a result, the NMOS transistor 57 and the PMOS transistor 56 are transferred to the glass substrate 38.

After removal of the delaminating layer 33 by etching and the like, the base layer 1 (including the n-well region 7) is thinned by etching, CMP, and the like until the LOCOS oxide film 10 is exposed for element isolation. This step of etching the base layer 1 until exposure of the LOCOS oxide film 10 is not necessarily essential.

The heat treatment process is then performed, to remove hydrogen as the substance for delamination from the base layer 1. That is, heat treatment at 400 to 600° C. is performed for about 30 minutes to about four hours, to remove hydrogen in the base layer 1.

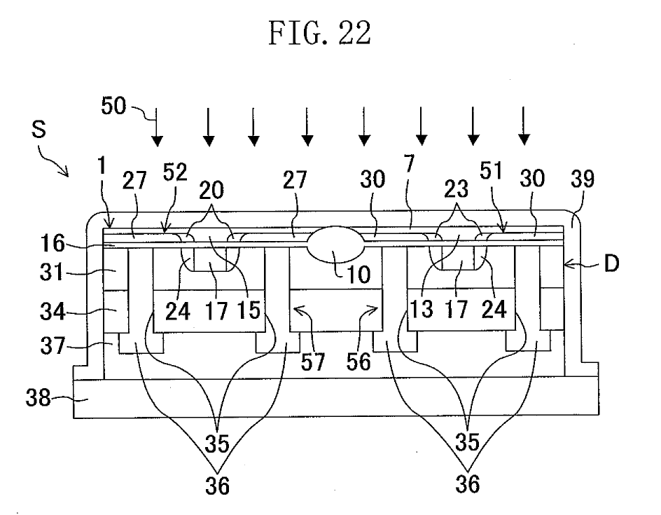

The insulating film formation step is then executed, in which, as shown in FIG. 22, an oxide film 39 is formed as an insulating film covering the delaminated surface of the base layer 1 to a thickness of 10 to 100 nm by CVD and the like. The oxide film 39 is formed over the surface of the element portion D including the sides thereof and the exposed surface of the glass substrate 38 on which the element portion D is not formed.

The ion implantation step is then executed, in which, as shown in FIG. 22, boron 50 as a p-type impurity element is ion-implanted in the base layer 1 through the oxide film 39. This is performed to adjust the impurity concentrations of the p-type regions of the NMOS transistor 57 and the PMOS transistor 56 thereby to set the threshold voltages of these transistors properly. In other words, the boron 50 is introduced from the side of the base layer 1 opposite to the side where the gate electrodes 17 exist.

With the above ion implantation, the threshold voltages of the NMOS transistor 57 and the PMOS transistor 56 are adjusted. The implantation conditions of the boron 50 are a dose of 1×10¹² to 1×10¹³ cm⁻² and energy of 20 to 100 KeV.

The thus-manufactured semiconductor device S has a region where the proportion of electrically active boron is in the range of 80% to 100% of the boron contained in the base layer 1. The concentration distribution of the boron contained in the base layer 1 and the oxide film 39 is continuous over the interface between the base layer 1 and the oxide film 39.

The interlayer insulating film 40 is then formed on the surface of the oxide film 39 as shown in FIG. 1. Thereafter, for activation of the implanted impurity element, heat treatment is performed at 500 to 600° C. for about 30 minutes to about four hours, or, to avoid adverse effect on the glass substrate 38, at 600 to 700° C. for a short time (ten minutes or less). The semiconductor device S is thus manufactured.

Advantages of Embodiment 1

According to Embodiment 1, the boron 50 for adjusting the impurity concentrations of the p-type regions of the NMOS transistor 57 and the PMOS transistor 56 thereby to set the threshold voltages of these transistors properly is ion-implanted after heating of the base layer 1. Therefore, since hydrogen contained in the base layer 1 can be removed in advance by heating in the separation step and the heat treatment step, the boron 50 introduced into the base layer 1 can be prevented from deactivation with hydrogen, maintaining its function as the p-type impurity element. In other words, the threshold voltages of the NMOS transistor 57 and the PMOS transistor 56 can be adjusted properly with good accuracy and repeatability. Moreover, since the dose of the boron 50 into the base layer 1 can be reduced while the function of the p-type impurity element is maintained, reduction in mobility due to impurity scattering can be suppressed.

In the thus-manufactured semiconductor device S, the operating speed of the NMOS transistor 57 and the PMOS transistor 56 can be enhanced, and the parasitic capacitance thereof can be reduced.

Moreover, with the heat treatment step executed in addition to the heat treatment in the separation step, the base layer 1 can be sufficiently heated to ensure removal of hydrogen from the base layer 1.

### Other Embodiments

In Embodiment 1 above, the heat treatment step of heating the base layer 1 is executed separately from the separation step. Alternatively, the heat treatment step may be omitted, and removal of hydrogen from the base layer 1 may be performed during the heat treatment of the base layer 1 in the separation step. This can reduce the number of steps and hence reduce the cost.

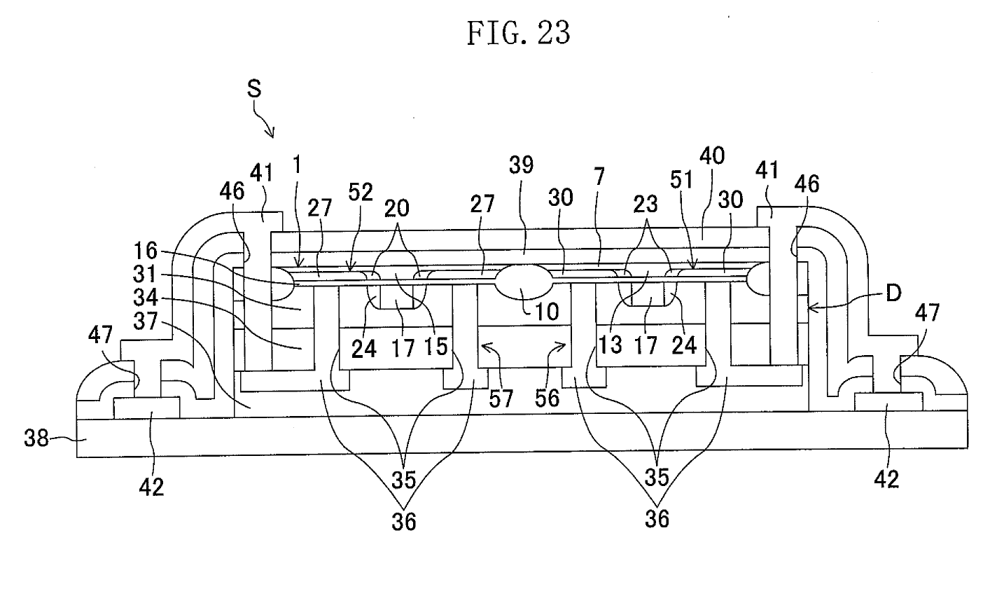

In Embodiment 1, the element portion D is bonded to the glass substrate 38. As shown in the cross section of FIG. 23, the NMOS transistor 57 and the PMOS transistor 56 of the element portion D bonded to the glass substrate 38 may be electrically connected to electric elements 42 formed in advance on the glass substrate 38.

More specifically, in the bonding step, the element portion D is bonded to the glass substrate 38 on which the electric elements 42 such as active elements and passive elements are formed in advance. The heat treatment step described above is then executed. After formation of the oxide film 39 to cover the element portion D and the electric elements 42 on the glass substrate, the ion implantation step is executed. The interlayer insulating film 40 is then formed to cover the oxide film 39. Thereafter, contact holes 46 are formed through the element portion D to expose the source and drain electrodes 36 at the bottom. Contact holes 47 are also formed on the sides of the element portion D through the oxide film 39 and the interlayer insulating film 40 to expose the electric elements 42 at the bottom. Metal interconnects 41 are then formed and patterned so that the source and drain electrodes 36 are connected to the electric elements 42 via the contact holes 46 and 47. The semiconductor device S may be formed in this manner.

In Embodiment 1, the MOS transistors were taken as examples of the elements. The present invention is not limited to this, but at least one type of MOS transistors, bipolar transistors, and diodes may be used as the elements.

For example, when the element is a MOS transistor, the present invention is applicable to the channel region of the MOS transistor as the p-type region. When the element is a bipolar transistor, the present invention is applicable to the base region of the bipolar transistor as the p-type region. When the element is a PN junction diode, the present invention is applicable to the p-type region of the PN junction diode as the p-type region.

In Embodiment 1, described was the method in which ion implantation of a p-type impurity element such as boron was principally omitted in the element portion formation step of forming the element portion D including at least part of the NMOS transistor 57 and the PMOS transistor 56 as elements on the base layer 1 that was a monocrystalline silicon semiconductor layer, for example.

Alternatively, ion implantation of a p-type impurity element such as boron may be performed in the element portion formation step. Thereafter, after the bonding to the glass substrate 38 and the separation, the boron 50 as the p-type impurity element may be ion-implanted in the base layer 1 through the oxide film 39 for setting the threshold voltages of the NMOS transistor 57 and the PMOS transistor 56.

As discussed earlier, in a case where ion implantation is performed in the element portion formation step, the dose of the p-type impurity such as boron implanted in the channel formation region must be increased in advance considering the deactivation of the p-type impurity element by bonding with hydrogen and the change of the channel region to n-type conductivity with thermal donors, thereby to finally adjust the concentration of the p-type impurity that electrically functions as the acceptor properly. In the above case, however, since the threshold voltages can be finally adjusted with the ion implantation after the bonding to the glass substrate 38 and the separation, the p-type impurity concentration can be set with good controllability compared with the case of performing ion implantation of the p-type impurity element only in the element portion formation process.

Ion implantation of the p-type impurity element may be performed in a slanting direction using the gate electrodes as a mask in areas of the channel region of a MOS transistor having fine sizes in plan that are in contact with the lightly doped impurity regions of the source and drain regions (halo implantation) for reduction of a short channel effect. In this case, ion implantation after the separation is not successful. Therefore, the p-type impurity element is preferably introduced in both the element portion formation step and the step after the bonding and the separation.

### INDUSTRIAL APPLICABILITY

As described above, the present invention is useful in semiconductor devices applied to liquid crystal displays, for example, and a method for manufacturing such semiconductor devices. In particular, the present invention is suited to forming an element once formed on a base layer on another substrate as a thinned element, and adjusting the impurity concentration of a p-type region of the element properly with good accuracy and repeatability.

1. A method for manufacturing a semiconductor device, comprising:
an element portion formation step of forming an element portion including at least part of an element on a base layer;
a delaminating layer formation step of forming a delaminating layer by ion-implanting a substance for delamination in the base layer;
a bonding step of bonding the base layer having the element portion to a substrate; and
a separation step of separating and removing a portion of the base layer in the depth direction in which the element portion is not formed along the delaminating layer by heating the base layer bonded to the substrate, wherein
the method further comprises, after the separation step, an ion implantation step of ion-implanting a p-type impurity element in the base layer for adjusting the impurity concentration of a p-type region of the element.

2. The method of claim 1, further comprising:
after the separation step, a heat treatment step of heating the base layer to remove the substance for delamination from the base layer.

3. The method of claim 1, further comprising:
an insulating film formation step of forming an insulating film covering a surface of the base layer subjected to the delamination, wherein
in the ion implantation step, the p-type impurity element is ion-implanted in the base layer through the insulating film.

4. The method of claim 1, further comprising:
after the separation step, a heat treatment step of heating the base layer to remove the substance for delamination from the base layer; and
an insulating film formation step of forming an insulating film covering a surface of the heat-treated base layer subjected to the delamination, wherein
in the ion implantation step, the p-type impurity element is ion-implanted in the base layer through the insulating film.

5. The method of claim 1, wherein
the p-type impurity element is boron.

6. The method of claim 1, wherein
the substrate is a glass substrate or a monocrystalline silicon semiconductor substrate.

7. The method of claim 1, wherein
the base layer includes at least one selected from the group consisting of monocrystalline silicon semiconductors, IV group semiconductors, II-VI group compound semiconductors, III-V group compound semiconductors, IV-IV group compound semiconductors, mixed crystals thereof including their homologous elements, and oxide semiconductors thereof.

8. The method of claim 1, wherein
the substance for delamination is hydrogen or an inert element.

9. The method of claim 1, wherein
the element is at least one of a MOS transistor, a bipolar transistor, and a diode.

10. The method of claim 1, wherein
the element is a MOS transistor, and
the p-type region is a channel region of the MOS transistor.

11. The method of claim 1, wherein
the element is a bipolar transistor, and
the p-type region is a base region of the bipolar transistor.

12. The method of claim 1, wherein
the element is a PN-junction diode, and
the p-type region is a p-type region of the PN-junction diode.

13. A semiconductor device having a base layer bonded to a substrate, a portion of the base layer having been separated and removed along a delaminating layer containing hydrogen, the base layer having an element portion including at least part of an element formed thereon, wherein
the base layer has a region containing a p-type impurity element in which the proportion of the electrically active p-type impurity element is in the range of 80% to 100% of the p-type impurity element contained in the base layer.

14. A semiconductor device having a base layer bonded to a substrate, a portion of the base layer having been separated and removed along a delaminating layer containing hydrogen, the base layer having an element portion including at least part of an element formed thereon, wherein
the semiconductor device includes an insulating film formed continuously on a surface of the base layer and a surface of a region of the substrate on which the base layer is not formed,
the base layer and the insulating film contain a p-type impurity element, and
the concentration distribution of the p-type impurity element contained in the base layer and the insulating film is continuous over the interface between the base layer and the insulating film.

15. The device of claim 13 or 14, wherein
the concentration of the p-type impurity element is in the range of 5×10¹⁶ cm⁻³ to 1×10¹⁸ cm⁻³.

16. The device of claim 14, wherein
the carrier concentration of the electrically active p-type impurity element is in the range of 5×10¹⁶ cm⁻³ to 1×10¹⁸ cm⁻³.

17. The device of claim 13 or 14, wherein
the p-type impurity element is boron.

18. The device of claim 13 or 14, wherein
the substrate is a glass substrate or a monocrystalline silicon semiconductor substrate.

19. The device of claim 13 or 14, wherein
the base layer includes at least one selected from the group consisting of monocrystalline silicon semiconductors, IV group semiconductors, II-VI group compound semiconductors, III-V group compound semiconductors, IV-IV group compound semiconductors, mixed crystals thereof including homologous elements, and oxide semiconductors thereof.

20. The device of claim 13 or 14, wherein
the element is at least one of a MOS transistor, a bipolar transistor, and a diode.

21. The device of claim 13 or 14, wherein
the element is a MOS transistor, and
the p-type region is a channel region of the MOS transistor.

22. The device of claim 13 or 14, wherein
the element is a bipolar transistor, and
the p-type region is a base region of the bipolar transistor.

23. The device of claim 13 or 14, wherein
the element is a PN-junction diode, and
the p-type region is a p-type region of the PN-junction diode.
